(19) United States
(12) Patent Application Publication
(10) Pub. No.: US 2025/0040047 A1
(43) Pub. Date: Jan. 30, 2025

(54) WIRING BOARD AND MOUNTING STRUCTURE USING SAME

(71) Applicant: KYOCERA Corporation, Kyoto-shi (JP)

(72) Inventor: Masashi OHMURA, Ritto-shi (JP)

(73) Assignee: KYOCERA Corporation, Kyoto-shi (JP)

(21) Appl. No.: 18/776,580

(22) Filed: Jul. 18, 2024

(30) Foreign Application Priority Data
Jul. 27, 2023 (JP) 2023-122506

(51) Int. Cl. H05K 1/11; H05K 1/03; H05K 1/18; H05K 3/42

(52) U.S. Cl. CPC H05K 1/115; H05K 1/0306; H05K 1/032; H05K 1/181; H05K 3/429; H05K 2201/09827; H05K 2203/041

(57) ABSTRACT

A wiring board according to the present disclosure includes an insulation layer having a first surface and a second surface located on the opposite side to the first surface, a through-hole penetrating the insulation layer from the first surface to the second surface, and a through-hole conductor located at least in the through-hole.

### BACKGROUND OF THE INVENTION

### 1. Technical Field

The present invention relates to a wiring board and a mounting structure using the wiring board.

### 2. Background

In order to electrically connect an upper surface side and a lower surface side of a wiring board, at least one through-hole is formed at an insulation layer of the wiring board. When the through-hole is viewed in a cross-sectional view in the depth direction thereof, the through-hole may have a constricted shape as described in JP 2016-213296 A and may include a wide-width part and a narrow-width part, depending on the formation method.

### SUMMARY

A wiring board according to the present disclosure includes an insulation layer having a first surface and a second surface located on the opposite side to the first surface, a through-hole penetrating the insulation layer from the first surface to the second surface, and a through-hole conductor located at least in the through-hole. The through-hole includes a narrowest portion at which an inner diameter of the through-hole is narrowest and a widest portion at which the inner diameter of the through-hole is widest. The through-hole conductor includes a first portion located at least at an inner wall surface of the through-hole and a second portion located to extend from the inner wall surface to an inside of the insulation layer. The second portion is located at least at the insulation layer adjacent to the narrowest portion in a cross-sectional view of the through-hole in a through direction, and is located between a first virtual line and a second virtual line, when the first virtual line is a virtual line passing through the narrowest portion of the inner wall surface and extending in parallel to a thickness direction of the insulation layer, and the second virtual line is a virtual line passing through the widest portion of the inner wall surface and extending in parallel to the thickness direction of the insulation layer.

A mounting structure according to the present disclosure includes the wiring board described above and an electronic component located at a mounting region of the wiring board.

### BRIEF DESCRIPTION OF THE DRAWINGS

FIG. 1 is an explanatory view for explaining a wiring board according to one embodiment of the present disclosure.

FIG. 2A is an enlarged explanatory view for explaining a region X illustrated in FIG. 1, FIG. 2B is a plane perspective view of a region A illustrated in FIG. 2A viewed from a direction of an arrow A, and FIG. 2C is an explanatory view illustrating another embodiment.

FIGS. 3A to 3H are explanatory views for explaining one embodiment of a method for forming a through-hole conductor located at the region X illustrated in FIG. 1.

### DETAILED DESCRIPTION

As described in JP 2016-213296 A, when a through-hole has a constricted shape, stress is likely to be concentrated on a narrow-width part. Thus, a through-hole conductor is likely to be disconnected at the narrow-width part. Therefore, a wiring board is required which can suppress disconnection of the through-hole conductor at a narrowest portion of the through-hole where stress is likely to be concentrated, and also reduces a risk of short circuit.

A wiring board according to the present disclosure has the configuration described above in the SUMMARY section, and thus can suppress disconnection of the through-hole conductor at the narrowest portion of the through-hole where stress is likely to be concentrated, and can also reduce the risk of short circuit.

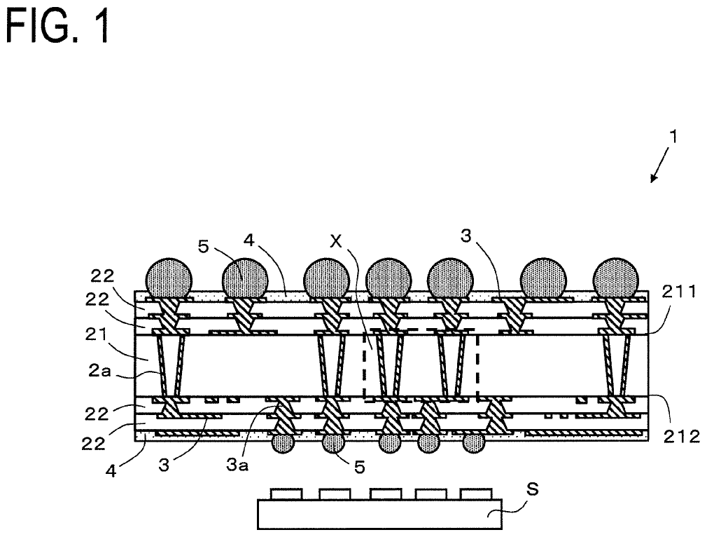

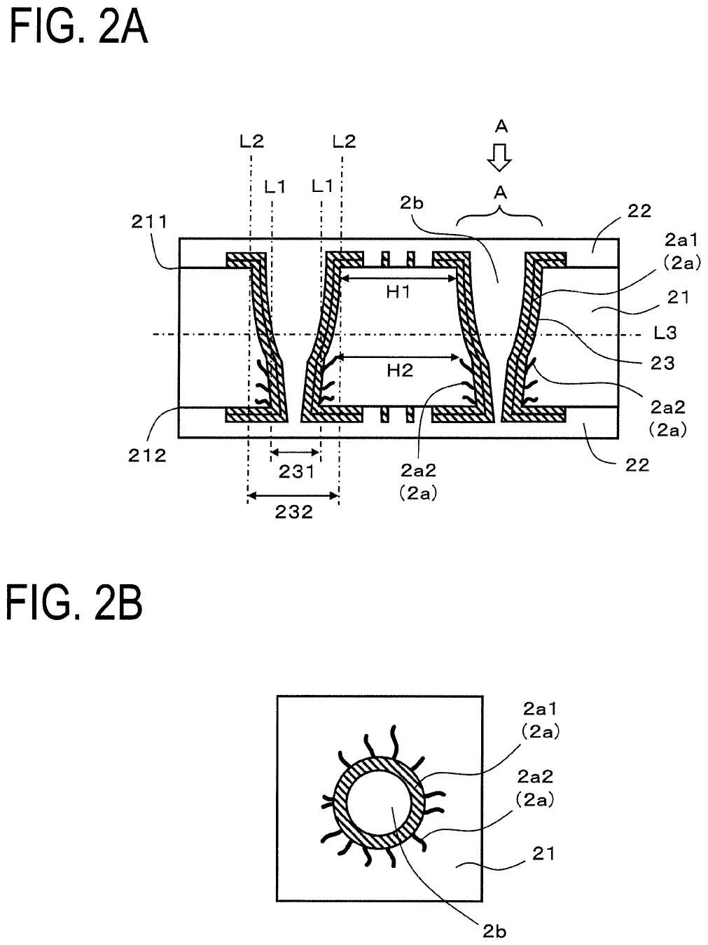

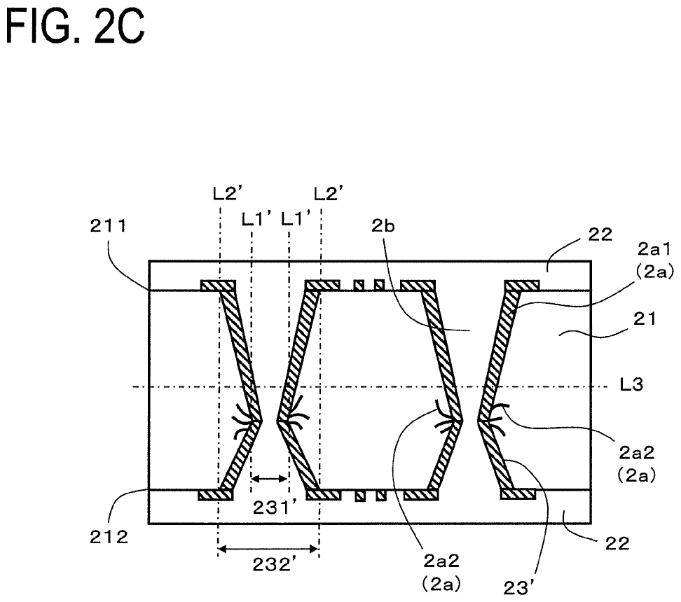

A wiring board according to one embodiment of the present disclosure will be described with reference to FIG. 1 and FIGS. 2A to 2C. FIG. 1 is an explanatory view for explaining a wiring board 1 according to one embodiment of the present disclosure. As illustrated in FIG. 1, the wiring board 1 according to one embodiment includes an insulation layer 21, build-up insulation layers 22, electrical conductor layers 3, and solder resists 4.

The insulation layer 21 has a first surface 211 and a second surface 212 located on the opposite side to the first surface 211. The insulation layer 21 is not particularly limited as long as it is made of a material having an insulating property. Examples of the material having an insulation property include insulating resins such as an epoxy resin, a bismaleimide-triazine resin, a polyimide resin, and a polyphenylene ether resin. Only a single type of these insulating resins may be used, or two or more may be mixed and used. The thickness of the insulation layer 21 is not particularly limited. The insulation layer 21 may have a thickness of, for example, 30 μm or more and 400 μm or less.

The insulation layer 21 may function as, for example, a core insulation layer in the wiring board 1. When the insulation layer 21 functions as the core insulation layer, the insulation layer 21 may contain a reinforcing material to improve the rigidity. Examples of the reinforcing material include insulating fabric materials such as glass fiber, glass non-woven fabric, aramid fiber, aramid non-woven fabric, and polyester fiber. Only a single type of these reinforcing materials may be used, or two or more may be combined and used. An inorganic insulation filler made of, for example, silica, barium sulfate, talc, clay, glass, calcium carbonate, or titanium oxide may be dispersed in the insulation layer 21. Only a single type of these inorganic insulation fillers may be used, or two or more may be combined and used.

On each of the first surface 211 and the second surface 212 of the insulation layer 21, a build-up layer is located in which the electrical conductor layer 3 and the build-up insulation layer 22 are alternately layered. The build-up insulation layer 22 is not particularly limited as long as it is made of a material having an insulating property. Examples of the material having an insulation property include insulating resins such as an epoxy resin, a bismaleimide-triazine resin, a polyimide resin, and a polyphenylene ether resin. Only a single type of these insulating resins may be used, or two or more may be mixed and used.

The build-up insulation layers 22 may be made of the same insulating resin or different resins. The build-up insulation layer 22 constituting the build-up layer and the insulation layer 21 may be made of the same insulating resin or different insulating resins. The thickness of the build-up insulation layer 22 is not particularly limited. The build-up insulation layers 22 have a thickness of, for example, 5 μm or more and 40 μm or less. The build-up insulation layers 22 may have the same thickness, or may have different thicknesses from each other.

The build-up insulation layer 22 may also contain a reinforcing material. Examples of the reinforcing material include insulating fabric materials such as glass fiber, glass non-woven fabric, aramid fiber, aramid non-woven fabric, and polyester fiber. Only a single type of these reinforcing materials may be used, or two or more may be combined and used. An inorganic insulation filler made of, for example, silica, barium sulfate, talc, clay, glass, calcium carbonate, or titanium oxide may be dispersed also in the build-up insulation layer 22. Only a single type of these inorganic insulation fillers may be used, or two or more may be combined and used.

The electrical conductor layer 3 is not limited as long as it is formed of a conductor such as a metal. Examples of such a conductor include metals such as copper. The thickness of the electrical conductor layer 3 is not particularly limited, and is, for example, in a range from 3 μm to 20 μm. The electrical conductor layer 3 includes a power supply conductor, a ground conductor, and a signal conductor.

A via-hole conductor 3a is located in the build-up insulation layer 22 in order to electrically connect the upper and lower surfaces of the build-up insulation layer 22. The via-hole conductor 3a is located in a via-hole that is formed so as to penetrate the build-up insulation layer 22. The via-hole conductor 3a is a part of the electrical conductor layer 3, and is formed of a metal such as copper.

As illustrated in FIG. 1, the solder resist 4 may be located at a surface of the build-up layer. The solder resist 4 is formed of a resin, and examples of the resin include an acrylic-modified epoxy resin. An opening is provided in the solder resist 4 in order to electrically connect the electrical conductor layer 3 and an electrode of an electronic component S via a solder 5. Examples of the electronic component S include a semiconductor integrated circuit element and an optoelectronic element.

A through-hole conductor 2a is located at the insulation layer 21 in order to electrically connect the upper and lower surfaces of the insulation layer 21. The through-hole conductor 2a is located inside a through-hole 23 penetrating the insulation layer 21 from the first surface 211 to the second surface 212. The through-hole conductor 2a is formed of, for example, metal plating such as copper plating.

As illustrated in FIG. 2A, the through-hole conductor 2a is located only at the inner wall surface of the through-hole 23. FIG. 2A is an enlarged explanatory view for explaining a region X illustrated in FIG. 1. A resin 2b is also located in the through-hole 23 in addition to the through-hole conductor 2a. The resin 2b is located so as to be surrounded by the through-hole conductor 2a. The resin 2b is a filling resin that fills a space surrounded by the through-hole conductor 2a.

The resin 2b is not limited, and examples of the resin 2b include insulating resins such as an epoxy resin, a bismaleimide-triazine resin, a polyimide resin, and a polyphenylene ether resin. Only a single type of these insulating resins may be used, or two or more may be mixed and used. Although the through-hole 23 is filled with the resin 2b in the wiring board 1, the through-hole 23 may be filled with the through-hole conductor 2a instead of the resin 2b.

The through-hole 23 does not have a constant inner diameter from the first surface 211 to the second surface 212. As illustrated in FIG. 2A, the through-hole 23 includes a narrowest portion 231 having the narrowest inner diameter and a widest portion 232 having the widest inner diameter.

When the through-hole 23 is viewed in a cross-sectional view in a through direction thereof, the narrowest portion 231 may be located closer to the first surface 211 side or the second surface 212 side than a position at half the thickness of the insulation layer 21. For example, as illustrated in FIG. 2A, at the wiring board 1, the narrowest portion 231 is located closer to the second surface 212 side than the position at half the thickness of the insulation layer 21. In FIG. 2A, the position at half the thickness of the insulation layer 21 is indicated by a line L3. When a high-density mounting region of a semiconductor element is located on the first surface 211 side, the narrowest portion 231 may be located on the first surface 211 side where stress is likely to be concentrated. Positioning the narrowest portion 211 on the first surface 211 side is advantageous in terms of being more likely to obtain a stress alleviating effect.

The through-hole conductor 2a includes a first portion 2a1 located at the inner wall surface of the through-hole 23, and a second portion 2a2 located so as to extend from the inner wall surface of the through-hole 23 to the inside of the insulation layer 21. The first portion 2a1 may be located at least at the inner wall surface of the through-hole 23. The through-hole conductor 2a located so as to fill the through-hole 23 also correspond to the first portion 2a1.

As illustrated in FIG. 2A, the second portion 2a2 is located at least at the insulation layer 21 adjacent to the narrowest portion 231 in a cross-sectional view of the through-hole 23 in the through direction thereof. When the second portion 2a2 is located at the insulation layer 21 adjacent to the narrowest portion 231, disconnection of the through-hole conductor 2a is suppressed. Specifically, when the second portion 2a2 is present, the adhesion of the through-hole conductor 2a is improved at the narrowest portion 231 where stress is likely to be concentrated. As a result, the disconnection of the through-hole conductor 2a is suppressed. The cross-sectional view in the through direction may be a view through the center of the through-hole 23. For example, when an opening of the through-hole 23 is circular in a plan view, the center of the through-hole 23 can be defined as a cross section passing through the center of the circle, and when the opening of the through-hole 23 is rectangular in a plan view, the center of the through-hole 23 can be defined as a cross section passing through an intersection point of diagonal lines of the rectangle.

As illustrated in FIG. 2B, the second portions 2a2 may be intermittently located at the peripheral edge of the through-hole 23 in a plane perspective view. FIG. 2B is a plane perspective view of a region A illustrated in FIG. 2A when viewed in a direction of an arrow A in FIG. 2A. For example, the second portions 2a2 may be arranged at equal intervals or may have the same length. When the second portions 2a2 are intermittently located at the peripheral edge of the through-hole 23, the adhesion of the through-hole conductor 2a is further improved. As a result, the disconnection of the through-hole conductor 2a is further suppressed.

As illustrated in FIG. 2A, the second portions 2a2 are located between a first virtual line L1 and a second virtual line L2 in a cross-sectional view of the through-hole 23 in the through direction thereof. Since the second portions 2a2 are located between the first virtual line L1 and the second virtual line L2, a shortest inter-wall distance H1 between the through-holes 23 adjacent to each other is always smaller than a shortest inter-wall distance H2 between the second portions 2a2 adjacent to each other. As a result, the shortest inter-wall distance H1 between the through-holes 23 adjacent to each other is formed at a predetermined value. Thus, the shortest distance H2 between the second portions 2a2 adjacent to each other is sufficiently secured, and thus a risk of short circuit is reduced.

As illustrated in FIG. 2A, the first virtual line L1 refers to a virtual line that passes through the narrowest portion 231 of the inner wall surface of the through-hole 23 and extends in parallel to the thickness direction of the insulation layer 21. The thickness direction of the insulation layer 21 can be defined as, for example, a direction perpendicular to the first surface 211 and/or the second surface 212 of the insulation layer 21. The second virtual line L2 refers to a virtual line that passes through the widest portion 232 of the inner wall surface of the through-hole 23 and extends in parallel to the thickness direction of the insulation layer 21.

When the insulation layer 21 is formed of the insulating resin as described above and includes the glass fiber as the reinforcing material, the second portion 2a2 may be located at least at one position selected from the group consisting of inside the glass fiber, between the glass fiber and the insulating resin, and inside the insulating resin. When the second portion 2a2 is located inside the glass fiber, the second portion 2a2 is firmly engaged with the glass fiber, which is advantageous for improving the connectivity between the through-hole conductor 2a and the insulation layer 21. The shape of the through-hole 23 in a cross-sectional view in the through direction thereof may be a shape as illustrated in FIG. 2C. In the shape illustrated in FIG. 2C, a narrowest portion 231′ is located between the line L3 indicating the position at half the thickness of the insulation layer 21 and the second surface 212 of the insulation layer 21. A first virtual line L1′, a second virtual line L2′, and a widest portion 232′ illustrated in FIG. 2C correspond to the first virtual line L1, the second virtual line L2, and the widest portion 232 described above, respectively, and thus a detailed description thereof is omitted here.

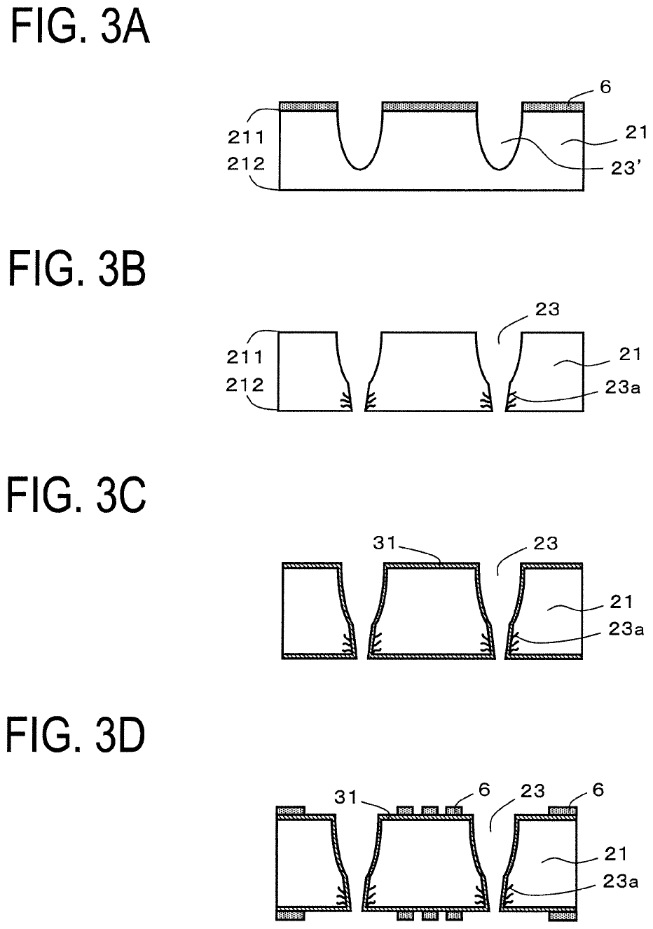

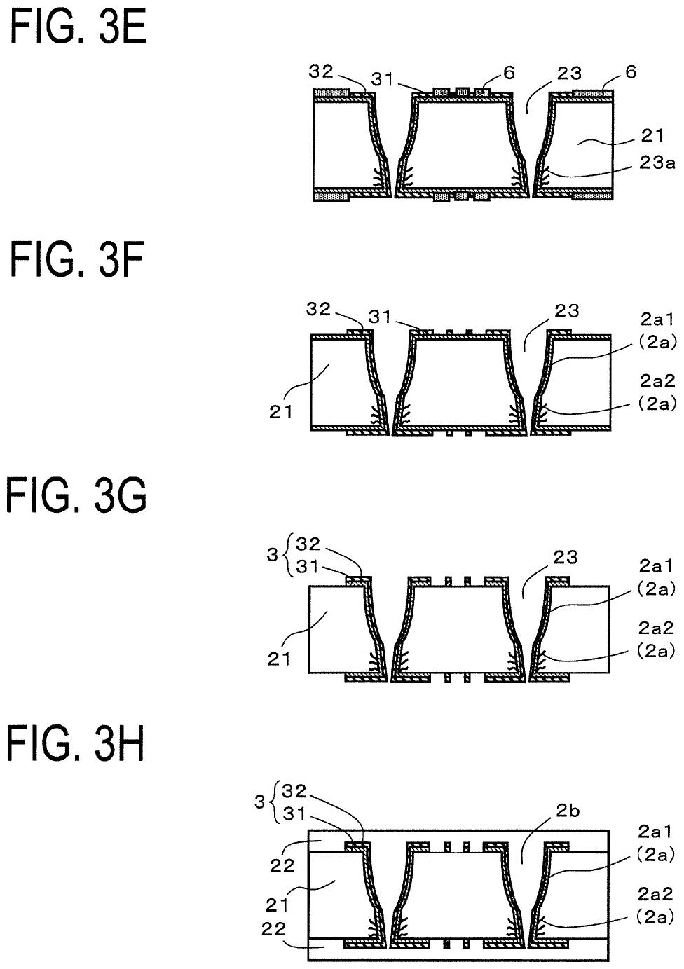

One embodiment of a method for forming the through-hole conductor 2a in the insulation layer 21 will be described based on FIGS. 3A to 3H. FIGS. 3A to 3H are explanatory views for explaining one embodiment of the method for forming the through-hole conductor 2a located in the region X illustrated in FIG. 1.

First, as illustrated in FIG. 3A, a recessed portion 23′ is formed in the insulation layer 21. Specifically, after covering the first surface 211 of the insulation layer 21 with a resist 6, the recessed portion 23′ is formed by, for example, blasting. The resist 6 may be, for example, a dry film resist. The size and the number of the recessed portion 23′ are the size and the number of the through-hole 23 to be finally formed, and are appropriately set in accordance with the size of the wiring board 1 and the like.

As illustrated in FIG. 3B, the through-hole 23 is formed by causing the recessed portion 23′ to penetrate the insulation layer 21 from the first surface 211 to the second surface 212. Specifically, the through-hole 23 is formed by removing the resist 6 and irradiating the recessed portion 23′ with a laser beam in order to cause the recessed portion 23′ to penetrate the insulation layer 21 from the first surface 211 to the second surface 212. In order to remove resin residues and the like, a desmear treatment or the like is performed as necessary. The inner diameter of the through-hole 23 is not constant, and the through-hole 23 includes a part having a narrow inner diameter and a part having a wide inner diameter. As illustrated in FIG. 2A, a part having the narrowest inner diameter is the narrowest portion 231, and a part having the widest inner diameter is the widest portion 232. The inner diameter of the through-hole 23 can be measured by, for example, a hole analyzer, X-ray observation, ultrasonic observation, or cross-sectional observation.

In the through-hole 23, a gap 23a is formed so as to extend from the inner wall surface of the through-hole 23 to the inside of the insulation layer 21. The gap 23a is formed mainly during a laser machining process, and is formed particularly in the vicinity of the narrowest portion 231 of the through-hole 23. When the insulation layer 21 contains the glass fiber as the reinforcing material, the gap 23a is also formed in the glass fiber.

As illustrated in FIG. 3C, a seed layer 31 is formed on the first surface 211 and the second surface 212 of the insulation layer 21 and on the inner wall surface of the through-hole 23. Forming the seed layer 31 allows a metal to be deposited efficiently by electrolytic plating. The seed layer 31 is formed of a metal such as copper, for example, by electroless plating or the like. The seed layer 31 is also formed in the above-described gap 23a.

As illustrated in FIG. 3D, parts of the seed layer 31 formed on the first surface 211 and on the second surface 212 of the insulation layer 21 are covered with the resist 6. The resist 6 is as described above, and thus a detailed description thereof is omitted here. The resist 6 has an opening at a position where the electrical conductor layer 3 is to be formed.

As illustrated in FIG. 3E, an electrolytic plating layer 32 is formed on the surface of the seed layer 31. Specifically, the electrolytic plating layer 32 is formed at a portion corresponding to the opening of the resist 6. The electrolytic plating layer 32 is formed by, for example, depositing a metal such as copper through electrolytic plating. The deposited portion of the electrolytic plating layer 32 corresponds to the electrical conductor layer 3. The electrolytic plating layer 32 is also formed in the above-described gap 23a.

The resist 6 is removed as illustrated in FIG. 3F. After removing the resist 6, the seed layer 31 that has been covered with the resist 6 is removed as illustrated in FIG. 3G. A method for removing the seed layer 31 is not limited, and examples thereof include an etching process such as flash etching.

As illustrated in FIG. 3H, the build-up insulation layers 22 are layered so as to cover the first surface 211 and the second surface 212 of the insulation layer 21 and the electrical conductor layer 3 formed on the first surface 211 and the second surface 212. The build-up insulation layer 22 is as described above, and thus a detailed description thereof is omitted here.

When the build-up insulation layers 22 are layered, the through-hole 23 is filled with a part of the resin forming the build-up insulation layers 22. The filled resin corresponds to the resin 2b. The through-hole 23 may be filled with the resin 2b before layering the build-up insulation layers 22. In this case, the resin 2b may be the same resin forming the build-up insulation layer 22, or may be a different resin. The resin 2b is as described above, and thus a detailed description thereof is omitted here. When the via-hole conductor 3a and the through-hole conductor 2a are to be connected to each other in series, lid plating may be formed on the resin 2b, or the through-hole 23 may be filled with the through-hole conductor 2a instead of the resin 2b.

In this way, the through-hole conductor 2a is formed in the insulation layer 21.

A mounting structure according to the present disclosure includes the wiring board 1 according to one embodiment, and the electronic component S located at a surface of the wiring board 1. The electrical conductor layer 3 inside the opening of the solder resist 4 and the electrode of the electronic component S are connected to each other via the solder 5. As described above, examples of the electronic component S include the semiconductor integrated circuit element and the optoelectronic element. In the mounting structure according to the present disclosure, the electronic component S may be located at both surfaces of the wiring board 1, or the electronic component S may be located at one of the surfaces and, for example, a motherboard or the like may be located at the other surface.

An embodiment of the present disclosure has been described above. However, the invention according to the present disclosure is not limited to the above-described embodiment, and various modifications or improvements can be made within the scope of the present disclosure described in (1) and (5) below.

(1) A wiring board according to the present disclosure includes an insulation layer having a first surface and a second surface located on the opposite side to the first surface, a through-hole penetrating the insulation layer from the first surface to the second surface, and a through-hole conductor located at least in the through-hole. The through-hole includes a narrowest portion at which an inner diameter of the through-hole is narrowest and a widest portion at which the inner diameter of the through-hole is widest. The through-hole conductor includes a first portion located at least at an inner wall surface of the through-hole and a second portion located to extend from the inner wall surface to an inside of the insulation layer. The second portion is located at least at the insulation layer adjacent to the narrowest portion in a cross-sectional view of the through-hole in a through direction, and is located between a first virtual line and a second virtual line, when the first virtual line is a virtual line passing through the narrowest portion of the inner wall surface and extending in parallel to a thickness direction of the insulation layer, and the second virtual line is a virtual line passing through the widest portion of the inner wall surface and extending in parallel to the thickness direction of the insulation layer.

With regard to embodiments of the present disclosure, the following embodiments (2) to (4) are further disclosed.

(2) In the wiring board according to (1) above, the second portion is intermittently located at a peripheral edge of the through-hole in a plane perspective view.

(3) In the wiring board according to (1) or (2) above, the narrowest portion is located closer to the first surface side or the second surface side than a position at half a thickness of the insulation layer when viewed in a cross-sectional view of the through-hole in the through direction.

(4) In the wiring board according to any one of (1) to (3) above, the insulation layer contains glass fiber and an insulating resin, and the second portion is located at least at one position selected from the group consisting of inside the glass fiber, between the glass fiber and the insulating resin, and inside the insulating resin.

(5) A mounting structure according to the present disclosure includes the wiring board according to any one of (1) to (4) above, and an electronic component located in a mounting region of the wiring board.

### DESCRIPTION OF THE REFERENCE NUMERAL

1 Wiring board
21 Insulation layer
211 First surface
212 Second surface
22 Build-up insulation layer
23 Through hole
231, 231′ Narrowest portion
232, 232′ Widest portion
23′ Recessed portion
23a Gap
2a Through-hole conductor
2a1 First portion
2a2 Second portion
2b Resin
3 Electrical conductor layer
3a Via-hole conductor
31 Seed layer
32 Electrolytic plating layer
4 Solder resist
5 Solder
6 Resist

1. A wiring board comprising:
an insulation layer having a first surface and a second surface located on the opposite side to the first surface;
a through-hole penetrating the insulation layer from the first surface to the second surface; and
a through-hole conductor located at least in the through-hole, wherein
the through-hole comprises a narrowest portion at which an inner diameter of the through-hole is narrowest and a widest portion at which the inner diameter of the through-hole is widest,
the through-hole conductor comprises a first portion located at least at an inner wall surface of the through-hole and a second portion located to extend from the inner wall surface to an inside of the insulation layer,
the second portion is located at least at the insulation layer adjacent to the narrowest portion in a cross-sectional view of the through-hole in a through direction, and is located between a first virtual line and a second virtual line, the first virtual line being a virtual line passing through the narrowest portion of the inner wall surface and extending in parallel to a thickness direction of the insulation layer, the second virtual line being a virtual line passing through the widest portion of the inner wall surface and extending in parallel to the thickness direction of the insulation layer.

2. The wiring board according to claim 1, wherein
the second portion is intermittently located at a peripheral edge of the through-hole in a plane perspective view.

3. The wiring board according to claim 1, wherein
the narrowest portion is located closer to the first surface side or the second surface side than a position at half a thickness of the insulation layer when viewed in a cross-sectional view of the through-hole in the through direction.

4. The wiring board according to claim 1, wherein
the insulation layer contains glass fiber and an insulating resin, and
the second portion is located at least at one position selected from the group consisting of inside the glass fiber, between the glass fiber and the insulating resin, and inside the insulating resin.

5. The wiring board according to claim 2, wherein
the narrowest portion is located closer to the first surface side or the second surface side than a position at half a thickness of the insulation layer when viewed in a cross-sectional view of the through-hole in the through direction.

6. The wiring board according to claim 2, wherein
the insulation layer contains glass fiber and an insulating resin, and
the second portion is located at least at one position selected from the group consisting of inside the glass fiber, between the glass fiber and the insulating resin, and inside the insulating resin.

7. The wiring board according to claim 3, wherein
the insulation layer contains glass fiber and an insulating resin, and
the second portion is located at least at one position selected from the group consisting of inside the glass fiber, between the glass fiber and the insulating resin, and inside the insulating resin.

8. The wiring board according to claim 5, wherein
the insulation layer contains glass fiber and an insulating resin, and
the second portion is located at least at one position selected from the group consisting of inside the glass fiber, between the glass fiber and the insulating resin, and inside the insulating resin.

9. The wiring board according to claim 1, further comprising
an electronic component located at a mounting region of the wiring board.

10. The wiring board according to claim 2, further comprising
an electronic component located at a mounting region of the wiring board.

11. The wiring board according to claim 3, further comprising
an electronic component located at a mounting region of the wiring board.

12. The wiring board according to claim 4, further comprising
an electronic component located at a mounting region of the wiring board.

13. The wiring board according to claim 5, further comprising
an electronic component located at a mounting region of the wiring board.

14. The wiring board according to claim 6, further comprising
an electronic component located at a mounting region of the wiring board.

15. The wiring board according to claim 7, further comprising
an electronic component located at a mounting region of the wiring board.

16. The wiring board according to claim 8, further comprising
an electronic component located at a mounting region of the wiring board.
